(19) United States
(12) Patent Application Publication
(10) Pub. No.: US 2024/0249919 A1
(43) Pub. Date: Jul. 25, 2024

(54) DC PULSE PLASMA SUBSTRATE TREATMENT APPARATUS

(71) Applicant: INNOVATION FOR CREATIVE DEVICES CO., LTD., Anseong-si (KR)

(72) Inventors: Buil JEON, Anseong-si (KR); Taeho SHIN, Yongin-si (KR); Dooho LIM, Suwon-si (KR); Jungsu PARK, Pyeongtaek-si (KR); Bumsoo ON, Yongin-si (KR); Seungho LEE, Yongin-si (KR)

(21) Appl. No.: 18/623,190

(22) Filed: Apr. 1, 2024

Related U.S. Application Data
(63) Continuation of application No. PCT/KR2022/015710, filed on Oct. 17, 2022.

(30) Foreign Application Priority Data
Oct. 20, 2021 (KR) 10-2021-0139999

(51) Int. Cl. H01J 37/32

(52) U.S. Cl. CPC H01J 37/32357; H01J 37/32027; H01J 37/321; H01J 2237/334

(57) ABSTRACT

A substrate treatment apparatus, according to one embodiment of the present invention, comprises: a remote plasma generator for generating remote plasma and an active species; an upper chamber having an opening connected to an output port of the remote plasma generator, and receiving and diffusing the active species of the remote plasma generator; a lower chamber for receiving the active species which has been diffused in the upper chamber; a main baffle for partitioning the upper chamber and the lower chamber and permeating the active species; a substrate holder for supporting a substrate disposed in the lower chamber; a RF power source for forming main plasma by applying RF power to the substrate holder; and a DC pulse power source for applying a DC pulse to the substrate holder.

### CROSS-REFERENCE TO RELATED APPLICATIONS

This application is a continuation of and claims priority to PCT/KR2022/015710 filed on Oct. 17, 2022, which claims priority to Korea Patent Application No. 10-2021-0139999 filed on Oct. 20, 2021, the entireties of which are both hereby incorporated by reference.

### TECHNICAL FIELD

The present disclosure relates to a DC pulse plasma apparatus, and relates to a plasma substrate apparatus for treating a substrate by receiving radicals, generated from a remote plasma generator and diffusing in an upper chamber and proving the received radicals to an lower chamber and applying a DC pulse to a substrate holder while generating capacitively-coupled plasma in the lower chamber.

### BACKGROUND ART

Plasma treatment devices are used for etching, cleaning, surface treatment, or the like. For example, plasma etching treatment devices require independent control of active species density, plasma density, and ion energy to obtain high etching selectivity and etching rate. A low-frequency RF power source below a band of several MHz is mainly used to control ion energy, and a high-frequency RF power source above a band of tens of MHz is mainly used to control plasma density and active species density. In addition, power of the low-frequency RF power source is increased to increase ion energy. Increasing the power of the high-frequency RF power source is required to increase plasma density. However, increasing the power of the high-frequency RF power source may cause gases to be over-decomposed, which may reduce etching selectivity. An electrostatic chuck is easily damaged by a high voltage.

Pulse plasma may change plasma characteristics by turning RF power on and off to reduce electron temperature and plasma density in a power-off interval. Accordingly, pulse plasma may reduce notching and bowing.

A conventional plasma device having a dual chamber structure includes an upper chamber and a lower chamber separated by a diffusion plate. Each of the upper and lower chambers generates plasma, and the diffusion plate separates each plasma region and is used as a path for movement of active species. Due to non-uniformity of the plasma in the upper chamber, the diffusion plate makes it difficult to control spatially uniform active species in the lower chamber. A structure of the diffusion plate for preventing mutual plasma diffusion makes it difficult to control pressure independently. Accordingly, the upper and lower chambers have limitations in securing desired plasma characteristics. The diffusion plate has a through-hole having a sufficiently small diameter to prevent mutual leakage of the upper and lower plasmas. Thus, conductance of the diffusion plate is reduced, the active species are deposited on the diffusion plate as foreign subjects, and the deposited foreign subjects may be separated to release contaminated particles. In addition, the plasma in the lower chamber interferes with the plasma in the upper chamber, and the plasma in the lower chamber has difficulty in plasma spatial uniformity due to non-uniformity of active species, or the like.

### DISCLOSURE OF THE INVENTION

### Technical Problem

The present disclosure provides a substrate treatment apparatus for performing a plasma process of high aspect ratio by applying high-frequency RF power to a DC pulse to a substrate.

### Technical Solution

A plasma substrate treatment apparatus according to an embodiment includes: a remote plasma generator generating remote plasma and active species; an upper chamber having an opening connected to an output port of the remote plasma generator and receiving and diffusing the active species from the remote plasma generator; a lower chamber receiving the diffused active species from the upper chamber; a main baffle partitioning the upper chamber and the lower chamber and allowing the active species to permeate therethrough; a substrate holder supporting a substrate disposed within the lower chamber; an RF power source applying RF power to the substrate holder to generate main plasma; and a DC pulse power source applying a DC pulse to the substrate holder.

In an embodiment, the RF power source may be an RF power source of more than 13.56 MHz and less than 60 MHz.

In an embodiment, the plasma substrate treatment apparatus may further include: a pulse control unit controlling the DC pulse power source and the RF power source. Each of the DC pulse power source and the RF power source may operate in pulse mode, the RF power source may include a first interval having first power and a second interval having second power lower than the first power, and the DC pulse power source may be turned on within the second interval.

In an embodiment, the plasma substrate treatment apparatus may further include: a capacitor disposed between the DC pulse power and the substrate holder. The RF power source may be connected to the substrate holder through the capacitor.

In an embodiment, the plasma substrate treatment apparatus may further include: an RF filter disposed between the DC pulse power source and the capacitor. The RF filter may block an RF signal of the RF power source.

In an embodiment, capacitance of the capacitor may be smaller than parasitic capacitance of a parasitic capacitor of the substrate holder, a frequency of the DC pulse power source may be smaller than RC delay time that is a product of equivalent capacitance of the capacitance of the capacitor and the parasitic capacitance of the parasitic capacitor of the substrate holder and equivalent resistance of the main plasma, and the DC pulse power source may be a bipolar spike pulse on a side of the main plasma.

In an embodiment, capacitance of the capacitor may be smaller than capacitance of a parasitic capacitor of the substrate holder, and the capacitor may act as an RC differentiator for the DC pulse power source.

In an embodiment, the plasma substrate treatment apparatus may further include: a plasma blocking baffle disposed in the opening of the upper chamber.

In an embodiment, the main baffle may include: an upper baffle electrically grounded and opposing the upper chamber and comprising a plurality of first through-holes; and a lower baffle electrically grounded and spaced apart from the upper baffle and comprising a plurality of second through-holes.

In an embodiment, the second through-hole may be disposed to avoid overlapping the first through-hole.

In an embodiment, a diameter of the second through-holes may be more than twice a thickness of the plasma sheath between the lower baffle and plasma, and the plasma may permeate into the second through-hole.

In an embodiment, a gap between the upper baffle and the lower baffle may be less than or equal to several millimeters, and a gap between the substrate holder and a lower surface of the upper baffle may be larger than the gap between the upper baffle and the lower baffle.

In an embodiment, a diameter of the first through-hole of the upper baffle may be smaller than a diameter of the second through-hole of the lower baffle.

In an embodiment, the second through-hole may be disposed to avoid overlapping the first through-hole.

In an embodiment, a diameter of the upper baffle may be smaller than a diameter of the lower baffle.

In an embodiment, the plasma blocking baffle may include: a disk having an inclined outer surface; and a ring plate having an inclined inner surface and an inclined outer surface and disposed to surround the disk at a predetermined distance from the disk. The outer surface of the disk may have an outer diameter increasing with height, and the inner surface of the ring plate may have an inner diameter increasing with height.

In an embodiment, the disk and the ring plate may be fixed by a plurality of bridges, and the ring plate may be fixed to the upper chamber by a plurality of columns.

In an embodiment, the plasma blocking baffle may include a plurality of through-holes. Through-holes disposed in a central portion of the plasma blocking baffle may be holes inclined to be directed toward a central axis, and the through-holes disposed in an edge of the plasma blocking baffle may be holes inclined to be directed toward the outside.

In an embodiment, the plasma substrate treatment apparatus may further include: at least one ground ring. The ground ring may be disposed below the main baffle to surround plasma between the substrate holder and the main baffle and has a ring shape, and an inner diameter of the ground ring may be larger than an outer diameter of the substrate holder.

In an embodiment, the main baffle may include: an upper baffle electrically grounded, opposing the upper chamber, and comprising a plurality of first through-holes; and a lower baffle electrically grounded, spaced apart from the upper baffle, and comprising a plurality of second through-holes. The lower baffle may include: a perforated plate formed of a conductor; and a compensation plate that is an insulator or a semiconductor having a dielectric constant, and disposed below the perforated plate. The second through-hole of the lower baffle may be disposed to penetrate through the perforated plate and the compensation plate.

In an embodiment, the lower baffle may have a constant thickness, a thickness of the perforated plate may vary depending on a location, and a thickness of the compensation plate may vary depending on a location to maintain a thickness of the lower baffle constant.

In an embodiment, the compensation plate may include at least one of silicon, silicon oxide, silicon nitride, or silicon oxynitride.

In an embodiment, a thickness of the compensation plate may be largest in at least one of a central region and an edge region, the central region may have a circular shape, and the edge region may have a ring shape.

In an embodiment, the remote plasma generator may be an inductively-coupled plasma source comprising an induction coil wound around a dielectric cylinder.

In an embodiment, the output port of the remote plasma generator may have a diameter ranging from 50 millimeters to 150 millimeters, the upper chamber may have a truncated cone shape, and the opening of the upper chamber may be disposed in a truncated portion.

### Advantageous Effects

As set forth above, a plasma substrate treatment apparatus according to an example embodiment may improve characteristics of a plasma process by generating plasma with high-frequency RF power applied to a substrate holder, increasing ion energy using a DC pulse applied to the substrate holder, and irradiating electrons on a lower surface of a high aspect ratio pattern to neutralize charging caused by ions.

### BRIEF DESCRIPTION OF THE DRAWINGS

FIG. 1 is a conceptual diagram illustrating a plasma substrate treatment apparatus according to an embodiment of the present disclosure.

FIG. 2A is a diagram illustrating waveforms of RF power and DC pulse power in the plasma substrate treatment apparatus of FIG. 1.

FIG. 2B is a circuit diagram illustrating a DC pulse power source, a capacitor, and a parasitic capacitor in the substrate treatment apparatus of FIG. 1.

FIG. 3A is a diagram illustrating a DC pulse V1 and a bipolar spike pulse V2 of DC pulse power.

FIG. 3B is a diagram illustrating the bipolar spike pulse V2 depending on capacitance of a capacitor connected to a DC pulse power source.

FIG. 4A is a perspective view illustrating a plasma blocking baffle of the substrate treatment apparatus of FIG. 1.

FIG. 4B is a cross-sectional view illustrating the plasma blocking baffle of the substrate treatment apparatus of FIG. 4A.

FIG. 5A is a plan view illustrating a main baffle in the plasma substrate treatment apparatus of FIG. 1.

FIG. 5B is a cross-sectional view, illustrating a main baffle, taken along line A-A′ of FIG. 5A.

FIG. 6 is a conceptual diagram illustrating the main baffle and the substrate holder of the substrate treatment apparatus of FIG. 1.

FIG. 7 is a diagram illustrating signals of the RF power and the DC pulse power of the plasma substrate treatment apparatus of FIG. 1.

FIG. 8 is a diagram illustrating signals of the RF power and the DC pulse power of the plasma substrate treatment apparatus of FIG. 1.

FIG. 9 is a conceptual diagram illustrating a plasma substrate treatment apparatus according to an embodiment of the present disclosure.

FIG. 10 is a perspective view illustrating a main baffle according to an embodiment of the present disclosure.

FIG. 11 is a cross-sectional view illustrating a substrate holder and a main baffle of a plasma substrate treatment apparatus of FIG. 10.

FIG. 12 is a plan view illustrating a main baffle according to another embodiment of the present disclosure.

FIG. 13 is a conceptual diagram illustrating a main baffle according to another embodiment of the present disclosure.

FIG. 14 is a cut-away perspective view illustrating a lower baffle of the main baffle of FIG. 13.

FIG. 15 is a diagram illustrating a change in plasma density by the main baffle of FIG. 13.

FIG. 16 is a conceptual diagram illustrating a substrate treatment apparatus according to another embodiment of the present disclosure.

FIG. 17 is a cross-sectional view illustrating a plasma blocking baffle according to another embodiment of the present disclosure.

FIG. 18 is a cross-sectional view showing the plasma blocking baffle according to another embodiment of the present disclosure.

### MODE FOR CARRYING OUT THE INVENTION

High plasma density and high ion bombardment energy are required to etch a high aspect ratio pattern. Conventionally, two or more RF frequencies are used. A high-frequency RF signal increases plasma density, and a low-frequency RF signal applies ion energy. However, as an aspect ratio of a pattern increases, higher ion energy is required, and a high-frequency RF signal of a high RF power source is applied to a substrate holder or a substrate. As a high-frequency RF signal of a higher power source is applied, a high-frequency RF power source causes many issues. For example, an electrostatic chuck (ESC) may be damaged by an increase in power of the high-frequency RF power source.

A substrate processing apparatus according to an example embodiment of the present disclosure may etch a high aspect ratio pattern while maintaining a high etch rate.

A substrate processing apparatus according to an example embodiment of the present disclosure uses a high-frequency RF power source and a DC pulse power source of several hundred kHz. A high-frequency RF signal of the high-frequency RF power source is applied to a substrate holder to control an electron temperature, thereby controlling the generation of neutral species and polymer participating in the reaction. A DC pulse of the DC pulse power source generates a bipolar spike pulse when a voltage rises and falls. An RC differentiation circuit including a capacitor converts a DC pulse into a bipolar spike pulse. By adjusting a width of the bipolar spike pulse with the capacitance of a capacitor, ion bombardment energy and electron injection may be adjusted to control high aspect ratio etching characteristics.

As a process is performed, the capacitance of a capacitor mounted outside may be adjusted to adjust a width and/or a pulse height of the bipolar spike pulse. Accordingly, as etching is performed, electrons and ions may be sequentially supplied to a lower surface of an etching pattern regardless of the aspect ratio. A positive spike pulse may supply electrons to the lower surface of the etching pattern, and a negative spike pulse may supply high energy ions to the lower surface of the etching pattern to perform etching.

A phase between the RF pulse of the high-frequency RF power source and the DC pulse of the DC pulse power source may be adjusted. High frequency on-time generates ions, electrons, and neutral species, the DC pulse generates a bipolar spike pulse, and the positive spike pulse collides ions with high ion energy onto the substrate. An off-time during which no RF is applied is provided between the RF pulse of the high-frequency RF power source and the DC pulse of the DC pulse power source such that byproducts generated during etching may be sufficiently discharged from the etching pattern.

On the other hand, the high-frequency RF source may apply high power to a first interval. The high-frequency RF power may apply low power to a second interval to increase the safety of the plasma and apply minimum power to prevent plasma from being completely turned off. The DC pulse of the DC pulse power source may generate a bipolar spike pulse in the second interval, and the positive spike pulse may collide with ions having high ion energy onto the substrate.

For high aspect ratio etching, active species need to be supplied into a trench or a hole pattern. At the same time, high energy ions need to collide with a lower surface of the trench or the hole pattern to separate bonded etch byproducts from a surface. As a depth of the hole increases, it may be difficult to simultaneously supply active species and ions to the lower surface of the deep hole or trench and smoothly remove the etched byproducts. As the depth of the hole increases, high energy ions may reach a lower surface of the etching pattern to be charged, but electrons may not reach the lower surface of the etching pattern. However, according to the present disclosure, electrons may reach the lower surface of the etching pattern by the negative spike pulse to suppress an effect caused by charging of the substrate.

To address the above-described issues, the present disclosure uses a high-frequency RF to generate neutral species and a DC pulse to increase the ion bombardment energy. The high-frequency RF pulse may apply high power to increase plasma density, and, after a certain time, apply minimum power to a chamber to maintain plasma stability. The DC pulse may be applied after a high-frequency pulse is turned off (or in a low power state) or at the same time as the high-frequency pulse is turned off (or in the low power state).

There may be a certain time difference between a first interval, in which RF plasma is generated, and an on-time interval of the DC pulse. The time difference may provide time for the neutral species, present in a hole, to sufficiently escape. And then, when the DC pulse is turned on, it may collide with byproducts reacting with a surface to separate the byproducts from the surface. After the DC pulse is turned off, it may provide time for the etch byproducts to be sufficiently discharged. Then, the next cycle may be repeated. The DC pulse on time may be programmed to be adjusted such that ions having greater energy may reach a deeper location as the etching is performed.

A plasma substrate processing apparatus according to an embodiment of the present disclosure may simultaneously supply a DC pulse and high-frequency RF power to a lower electrode serving as a substrate holder. The DC pulse may act as an RC differentiator due to parasitic capacitance of an electrostatic chuck. The RC differentiator may generate a bipolar spike pulse with respect to the DC pulse voltage. The bipolar spike pulse may accelerate and provide cations to the substrate and provide more electrons to the substrate. A width of the bipolar spike pulse may be controlled by adjusting the capacitance of the capacitor connected in series to a parasitic capacitor of the electrostatic chuck. The accelerated cations and additional electrons may neutralize the substrate to reduce the charging effect in a deep hole of the substrate. In addition, active species may be supplied from an upper electrode serving as a main baffle, and the upper electrode may be maintained at ground. Accordingly, the high-frequency RF power generating active species may be reduced, and the ion energy may be controlled by the bipolar pulse.

A plasma substrate processing apparatus according to an embodiment of the present disclosure may independently generate plasma and active species using a spatially separated remote plasma generator and supply only active species to an upper chamber constituting a process chamber. The remote plasma generator may independently generate active species and plasma and does not interfere with an RF power source of the process chamber.

The process chamber includes an upper chamber and a lower chamber. Active species supplied to the upper chamber may be injected and diffused over a wide area by a plasma blocking baffle, and the upper chamber may provide a sufficient space for diffusion. A main baffle, disposed between the upper chamber and the lower chamber, may have an optimized structure that may block charged particles, such as ions and electrons generated in the lower chamber, while allowing active species in the upper chamber to pass through the lower chamber. The main baffle may move the active species to the lower chamber without loss and may diffuse the active species in a shortest distance to uniformly inject the diffused active species into the lower chamber.

A plasma processing apparatus according to an embodiment of the present disclosure may independently generate active species using a remote plasma generator and supply the active species to a process chamber including an upper chamber and a lower chamber. The remote plasma generator may eliminate electrical interference with the process chamber, and may independently generate active species under optimal plasma conditions. A plasma blocking baffle may remove plasma supplied by the remote plasma generator, and may supply only active species to the upper chamber. The plasma blocking baffle may inject and diffuse the active species over a wide area. The upper and lower chambers are separated by a main baffle. Active species in the upper chamber may permeate through a grounded main baffle to be supplied to the lower chamber. A substrate holder may be disposed in the lower chamber, and RF power applied to the substrate holder may generate capacitively-coupled plasma between a substrate on the substrate holder and the main baffle (ground). As the active species are independently supplied to the lower chamber, power of a high-frequency RF power source for generating active species in the lower chamber may be reduced. In addition, power of a DC pulse power source for controlling the ion energy may be reduced to be mainly used for controlling ion energy and electron injection.

In the plasma substrate processing apparatus according to an embodiment of the present disclosure, the plasma blocking baffle may distribute active species spatially uniformly, and the main baffle may be used as a ground electrode of the capacitively-coupled plasma generated in the lower chamber. The main baffle may have a multilayer structure with an upper baffle and a lower baffle spaced apart from each other. A lower baffle of the main baffle may have a sufficient diameter to allow plasma to permeate from a lower side, and the plasma permeating through an opening of the lower baffle may be blocked by an upper baffle. Both the upper and lower baffles of the main baffle may be grounded to increase a contact area with the plasma and increase a bias voltage applied to a plasma sheath on a substrate. Accordingly, power of the low frequency RF power source for controlling the ion energy incident on the substrate may be reduced.

When charged particles (ions or electrons) collide with a wall, the charged particles may be neutralized. Accordingly, a method of blocking the ions or electrons is to prevent the presence of through-holes and allow the ions or electrons collide by permeating through the main baffle. On the other hand, neutral species or active species do not lose much of reactivity thereof in collisions. The charged particles may be neutralized due to collisions while moving a lower portion to an upper portion, and the neutral species may move from an upper portion to a lower portion with minimal collisions. To this end, the main baffle may have a multilayer structure to have large vacuum conductance, and the openings of the upper baffle and the lower baffle may be designed to avoid overlapping each other.

The main baffle may include an upper baffle and a lower baffle having a perforated plate structure. Each of the upper baffle and the lower baffle may have a through-hole structure of various shapes such as a maximum-sized triangle, rectangle, or circle. When a plurality of perforated plates overlap each other to prevent the movement of charged particles, the perforated plates may not penetrate from top to bottom. In other words, particles cannot move from the bottom to the top without collision. A structure, which cannot move straightly from the bottom to the top without collision, may be designed to have maximum vacuum conductance. For example, when two perforated plates are used, a size of an opening formed in each of the perforated plates may be significantly increased such that each of the perforated plates has maximum conductance. When the two perforated plates overlap each other, there is no overlapping opening (penetrating portion).

In addition, a diameter of a hole of the lower baffle may be large enough to allow the plasma, generated in the lower chamber, to permeate through the lower baffle. For example, the diameter of the hole of the lower baffle may be several millimeters. The diameter of the hole of the lower baffle may be, in detail, 5 to 10 millimeters. The diameter of the hole in the lower baffle may be larger than a diameter of a hole of the upper baffle. Accordingly, plasma incident on the lower baffle may be blocked and neutralized by the upper baffle. In addition, a contact area with the plasma may be increased.

According to an example embodiment of the present disclosure, the main baffle may include an upper baffle and a lower baffle spaced apart from each other, and the lower baffle may oppose a substrate applied with power of the RF power source. Accordingly, a ratio of a surface area of the lower baffle contacting the plasma to an area of the substrate may depend on a voltage applied to the substrate. Accordingly, increasing the surface area of the lower baffle contacting the plasma may increase a DC bias voltage applied to the substrate. As a result, higher ion energy may be obtained at the same RF power.

According to an example embodiment of the present disclosure, the lower baffle of the main baffle may have a two-layer stacked structure. In the case of high-frequency RF plasma, a spatially non-uniform plasma density distribution may be formed due to a standing wave effect or a harmonic effect. For example, a spatial distribution in a plasma radius direction may have a central peak and/or an edge peak. However, the plasma density may increase as a frequency of the RF power source increases, and high-frequency RF power of 60 MHz or higher may be used. However, such high-frequency RF power of 60 MHz or higher may generate a spatially non-uniform plasma density distribution due to the standing wave effect or the harmonic effect. At least one ground ring may be disposed to surround a discharge region to significantly reduce an effect on the conductance of gas, increase a resonant frequency to suppress the standing wave effect, and increase a grounding area.

According to an example embodiment of the present disclosure, with the help of a remote plasma generator, high-frequency RF power of 60 MHz or higher may not be used to increase the plasma density.

According to an example embodiment of the present disclosure, even when high-frequency RF power of 60 MHz or lower is used, the central peak and/or the edge peak may be controlled. Spatial control of the electric field strength may be performed by adjusting the gap distribution between the upper electrode main baffle and the lower electrode substrate holder. When a step is provided on a lower surface of the grounded upper electrode main baffle to adjust a gap between the grounded upper electrode (main baffle) and the lower electrode (substrate holder), the step on the lower surface of the grounded upper electrode (main baffle) may affect conductance when gas moves through the main baffle. In addition, the step on the lower surface of the upper electrode (main baffle) may act as an obstacle to a flow of the gas in a discharge space. In addition, contaminants may be attached to a step portion on the lower surface of the upper electrode (main baffle).

According to an example embodiment of the present disclosure, the lower baffle of the main baffle may spatially maintain the same thickness to eliminate the effect on the conductance when the active species move through the lower baffle. For example, the lower baffle may include an upper conductive perforated plate and a lower dielectric compensation plate. The lower baffle may include a compensation plate formed of an additional dielectric or semiconductor to remove obstacles to the flow of the gas in the discharge space. A lower surface of the lower baffle may be a flat plane. The closer a dielectric constant of a compensation layer is to a vacuum dielectric constant, the more advantageous it may be. The compensation layer may be silicon, silicon oxide, silicon nitride, silicon oxynitride, or aluminum oxide. A thickness of the compensation layer may vary depending on a location. As the thickness of the compensation layer increases, the electric field strength in the discharge space in a corresponding location may decrease. Accordingly, the spatial distribution of the thickness of the compensation layer may control the central peak and/or the edge peak. The compensation layer may be decomposed and combined with the conductive perforated plate of the lower baffle. The compensation layer may be replaced with a new component as a consumable.

According to an example embodiment of the present disclosure, the lower baffle may further include a plurality of trenches and/or holes formed on the lower baffle to increase a contact area with plasma. The plurality of trenches and/or holes may increase the contact area with the plasma.

According to an example embodiment of the present disclosure, guard rings having a ring structure may be disposed to surround the discharge space between the main baffle and the substrate holder. The guard rings may be grounded to increase a ground area of the plasma. In addition, the guard rings may be used to inhibit the diffusion of the plasma and confine the plasma to the discharge space. The guard rings may be stacked vertically and grounded. Process byproducts may diffuse through the space between the guard rings to be discharged through a vacuum pump.

According to an example embodiment of the present disclosure, the high-frequency RF power and the low-frequency RF power applied to the substrate holder may be synchronized with each other to operate in pulse mode. The high-frequency RF power may include a high-power interval and a low-power interval, and the low-frequency RF power may have an ON interval in the low-power interval of the high-frequency RF power.

The substrate processing apparatus may filter charged particles in etching, deposition, cleaning, and other devices in the semiconductor process, and may allow only reactive species having reactivity to be used in a process apparatus.

The plasma substrate processing apparatus according to an example embodiment of the present disclosure may be applied to an atomic layer etching apparatus for semiconductor etching, a plasma cleaning apparatus, a deposition apparatus using plasma, or the like.

The plasma blocking baffle may significantly reduce loss caused by collision while the active species are diffused downwardly, and may uniformly diffuse the active species from an upper area having a diameter of about 10 cm to a lower area having a diameter of about 40 cm in a shortest distance.

Hereinafter, example embodiments will now be described more fully with reference to the accompanying drawings, in which some example embodiments are shown. Example embodiments may however, be embodied in many different forms and should not be construed as being limited to the embodiments set forth herein. Rather, these example embodiments are provided so that this disclosure will be thorough and complete, and will fully convey the scope of example embodiments of the present disclosure to those of ordinary skill in the art. In the drawings, the thicknesses of layers and regions are exaggerated for clarity. Like reference characters and/or numerals in the drawings denote like elements.

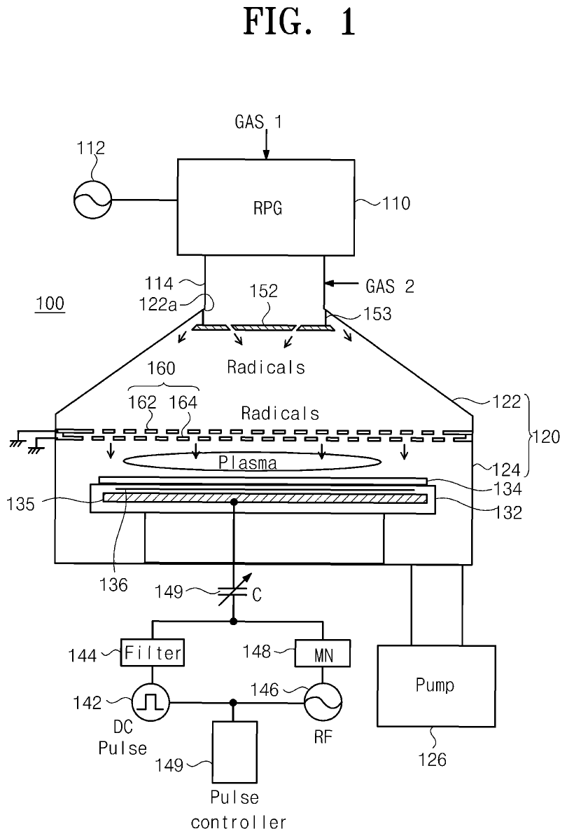

FIG. 1 is a conceptual diagram illustrating a plasma substrate treatment apparatus according to an embodiment of the present disclosure.

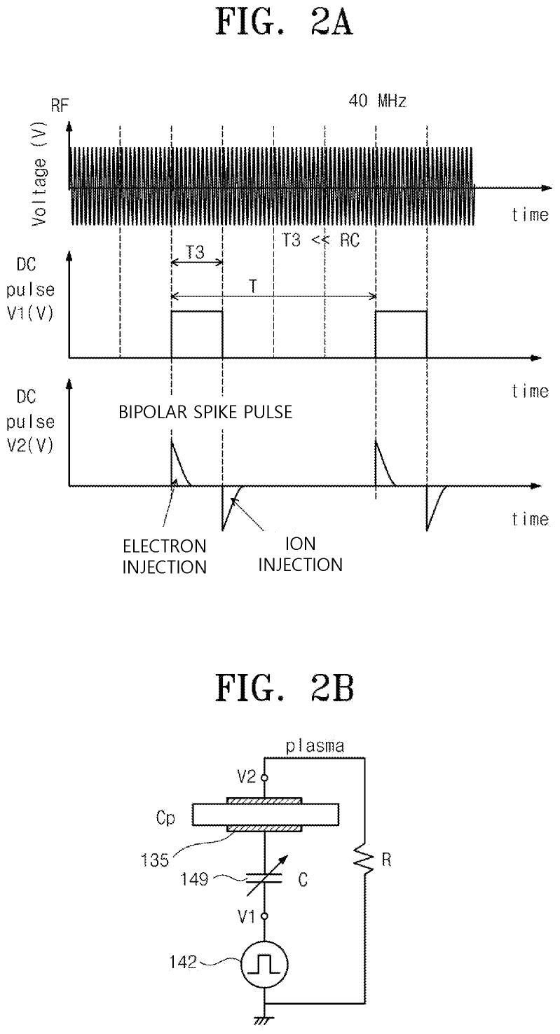

FIG. 2A is a diagram illustrating waveforms of RF power and DC pulse power in the plasma substrate treatment apparatus of FIG. 1.

FIG. 2B is a circuit diagram illustrating a DC pulse power source, a capacitor, and a parasitic capacitor in the substrate treatment apparatus of FIG. 1.

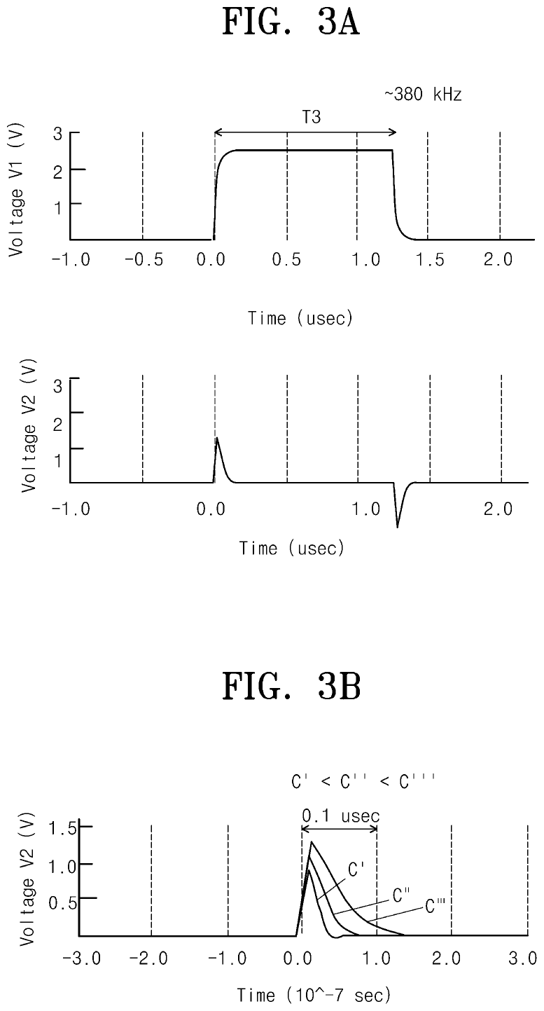

FIG. 3A is a diagram illustrating a DC pulse V1 and a bipolar spike pulse V2 of DC pulse power.

FIG. 3B is a diagram illustrating the bipolar spike pulse V2 depending on capacitance of a capacitor connected to a DC pulse power source.

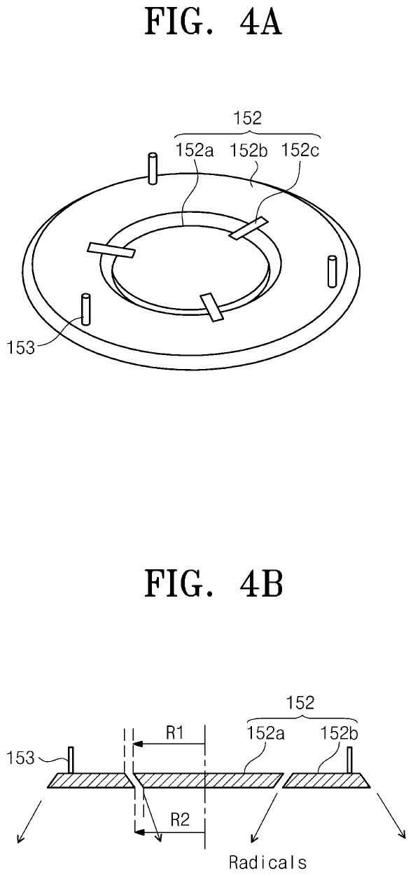

FIG. 4A is a perspective view illustrating a plasma blocking baffle of the substrate treatment apparatus of FIG. 1.

FIG. 4B is a cross-sectional view illustrating the plasma blocking baffle of the substrate treatment apparatus of FIG. 4A.

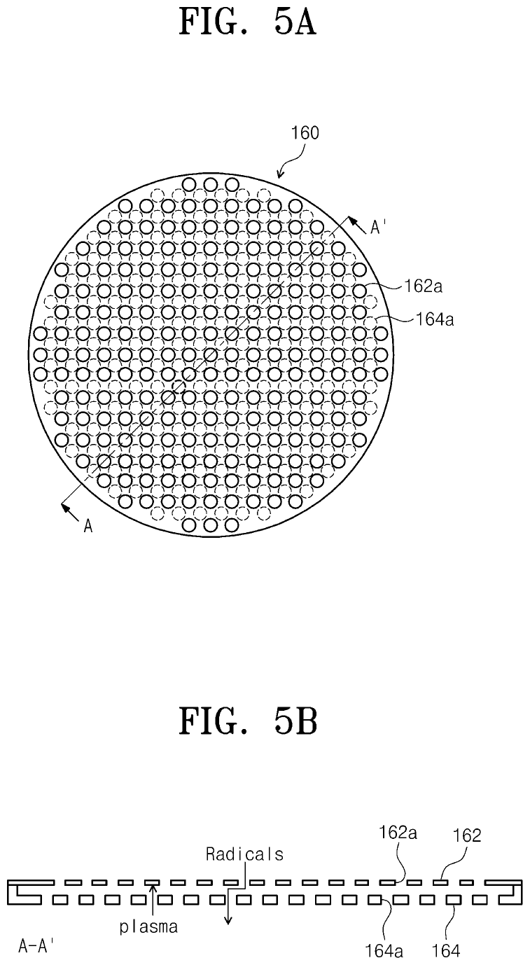

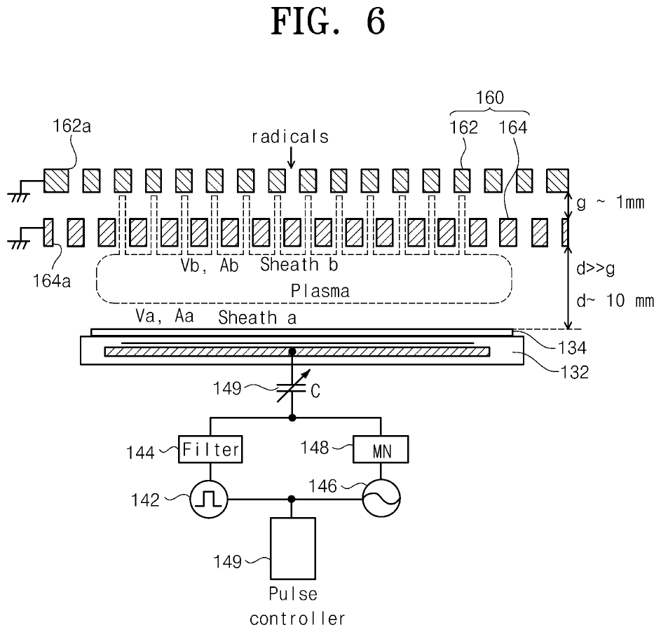

FIG. 5A is a plan view illustrating a main baffle in the plasma substrate treatment apparatus of FIG. 1.

FIG. 5B is a cross-sectional view, illustrating a main baffle, taken along line A-A′ of FIG. 5A.

FIG. 6 is a conceptual diagram illustrating the main baffle and the substrate holder of the substrate treatment apparatus of FIG. 1.

Referring to FIGS. 1 to 6, a plasma substrate processing apparatus 100 includes: a remote plasma generator 110 generating remote plasma and active species; an upper chamber 122 having an opening 122a connected to an output port 114 of the remote plasma generator 110 and receiving and diffusing the active species from the remote plasma generator 110; a lower chamber 124 receiving the diffused active species from the upper chamber 122; a main baffle 160 partitioning the upper chamber and the lower chamber and allowing the active species to permeate therethrough; a substrate holder 132 supporting a substrate disposed in the lower chamber; an RF power source 146 applying RF power to the substrate holder 132 to generate main plasma; and a DC pulse power source 142 applying a DC pulse to the substrate holder 132.

The plasma substrate processing apparatus 100 may be an etching apparatus, a cleaning apparatus, a surface treatment apparatus, or a deposition apparatus. The substrate may be a semiconductor substrate, a glass substrate, or a plastic substrate.

The remote plasma generator 110 may be an inductively-coupled plasma source including an induction coil (not illustrated) wound around a dielectric cylinder. The dielectric cylinder may be supplied with a first gas from the outside. A diameter of the dielectric cylinder may be 50 mm to 150 nm. The induction coil may be wound around the dielectric cylinder at least one turn, and may be supplied with RF power from a remote plasma RF power source 112. The frequency of the remote plasma RF power source 112 may be 400 kHz to 13.56 MHz. The induction coil may generate an inductively-coupled plasma inside the dielectric cylinder. Output power of the remote plasma RF power source may be several kW to several tens of kW. Accordingly, operating pressure of the remote plasma generator 110 may be several hundred mTorr to several tens of Torr. In the case of an etching process, the first gas may include a fluorine-containing gas. The remote plasma generator 110 may generate remote plasma and active species or neutral species decomposed from the first gas. The remote plasma generator 110 may control only characteristics of the plasma without considering the plasma spatial uniformity. An electron temperature may depend on pressure, and the plasma density may depend on the output power of the remote plasma RF power source. The remote plasma RF power source 112 may operate in continuous mode or pulse mode to control the characteristics of the remote plasma. Accordingly, the remote plasma generator 110 may independently control the density of active species and a density ratio of active species. For example, the remote plasma generator 110 may independently control the electron temperature using pressure and RF pulse mode. Accordingly, the density ratio of active species F, CF, CF₂, and CF₃ decomposed from CₓF_{y} gas may be controlled.

The active species may be provided to a process chamber 120. The process chamber 120 may include an upper chamber 122 and a lower chamber 124. The remote plasma generator 110 may be connected to the upper chamber 122 through the output port 114. A second gas may be additionally supplied to the output port 114. The second gas may be the same as or different from the first gas. The second gas may collide with the active species to reduce the temperature of the active species. The second gas may include at least one of oxygen-containing gas, hydrogen gas, and inert gas that is easy to generate plasma in the lower chamber.

The upper chamber 122 may have a truncated cone shape. The opening 122a of the upper chamber 122 may be disposed in a truncated portion. A lower portion of the upper chamber 122 may have a cylindrical shape. The upper chamber 122 may be formed of metal or a metal-alloy, and may be grounded.

The plasma blocking baffle 152 may include: a disk 152a having an inclined outer surface; and a ring plate 152b having an inclined inner surface and an inclined outer surface and disposed to surround the disk 152a at a predetermined distance from the disk 152a. The outer surface of the disk 152a may have an outer diameter increasing with height. The inner surface of the ring plate 152b may have an inner diameter increasing with height. The disk 152a and the ring plate 152b may be fixed by a plurality of bridges 152c. The ring plate 152b may be fixed to the upper chamber 122 by a plurality of columns 153.

A space between the disk 152a and the ring plate 152b may form a concentric slit. Active species, permeating through the concentric slit, may be injected and diffused in a direction of a center of the upper chamber 122. An outer surface of the ring plate 152b may have an outer diameter decreasing with height. Active species, permeating through a space between the outer surface of the ring plate and the upper chamber may be injected and diffused in a direction of a wall of the upper chamber 122. Accordingly, the active species may be widely diffused within the upper chamber 122 to form a uniform density distribution. The plasma blocking baffle 152 may spatially distribute the active species for rapid diffusion. Accordingly, a height of the upper chamber 122 may be reduced.

The plasma blocking baffle 152 may be formed of a conductive material or an insulating material. The plasma blocking baffle 152 may serve as a plasma blocking filter blocking plasma, generated from the remote plasma generator 110, and allowing active species to permeate therethrough. In addition, the plasma blocking baffle 152 may serve to spatially distribute the active species. Vertically incident ions may collide with the inclined surface of the plasma blocking baffle 152 while passing through the concentric slit of the plasma blocking baffle 152. A maximum diameter R1 on the inclined outer surface of the disk 152a may be larger than a minimum diameter R2 on the inclined inner surface of the ring plate 152b.

According to a modified embodiment of the present disclosure, the ring plate 152b may be provided in plural. Accordingly, a concentric slit between the ring plates 152b may block the plasma through the inclined surface and inject active species in a specific direction. Accordingly, the plasma blocking baffle 152 may provide sufficient conductance by a plurality of concentric slits. A height of the upper chamber 122 may be decreased.

The inside of the lower chamber 124 may have a cylindrical shape, and the lower chamber 124 may be formed of metal or a metal-alloy. The lower chamber 124 may be continuously connected to the upper chamber 122. A vacuum pump 126 may be connected to the lower chamber 124 to exhaust the lower chamber 124. In addition, a pressure of the lower chamber 124 may be several tens of mTorr to several hundreds of mTorr. Also, the pressure of the upper chamber 122 may be higher than a pressure of the lower chamber.

The main baffle 160 may be disposed in a cylindrical portion of the process chamber 120 to separate the upper chamber 122 and the lower chamber 124. The main baffle 160 may supply the active species of the upper chamber 122 to the lower chamber 124. The main baffle 160 may neutralize the capacitively-coupled plasma of the lower chamber 124 to prevent the capacitively-coupled plasma from permeating into the upper chamber 122 and increase a contact area with the capacitively-coupled plasma.

The main baffle 160 may include: an upper baffle 162 electrically grounded and opposing the upper chamber 122 and including a plurality of first through-holes 162a; and a lower baffle 164 electrically grounded and spaced apart from the upper baffle 162 and including a plurality of second through-holes 164a. Second through-hole 164a may be disposed to avoid overlapping the first through-holes 162a.

A thickness of the upper baffle 162 may be smaller than a thickness of the lower baffle 164. Accordingly, the upper baffle 162 may provide sufficiently large conductance with the first through-holes 162a due to a small thickness. The lower baffle 164 may increase the contact area with the plasma due to the small thickness.

A diameter of the second through-hole 164a may be more than twice a thickness of a plasma sheath between the lower baffle 164 and the plasma. Specifically, the diameter of the second through-hole 164a may be 5 millimeters to 10 millimeters. Accordingly, the plasma may permeate into the second through-hole 164a. The second through-hole 164a of the lower baffle 164 may increase a contact area with the plasma. The plasma, permeating into the second through-hole 164a, may collide with the upper baffle 162 to be neutralized. The upper baffle 162 may further increase the contact area with the plasma.

A gap between the upper baffle 162 and the lower baffle 164 may be less than several millimeters. Specifically, the gap g between the upper baffle 162 and the lower baffle 164 may be at a level of 1 millimeter to 5 millimeters. The gap g between the upper baffle and the lower baffle is small enough to prevent plasma, reaching the upper baffle 162 through the second through-hole 164a, from diffusing in a lateral direction.

A gap d between the lower surface of the upper baffle 164 and the substrate holder 132 may be larger than the gap g between the upper baffle and the lower baffle. A gap g between the substrate holder and the lower surface of the upper baffle may be 10 millimeters to 30 millimeters.

The substrate holder 132 may support a substrate 134 and receive power from the RF power source 146 to generate capacitively-coupled plasma. The substrate holder 132 may receive power from the DC pulse power source 142 to control the energy of ions incident on the substrate 134 and allow more electrons to be incident on the substrate 134.

The substrate holder 132 may include an electrode 136 for an electrostatic chuck. The electrostatic chuck may be supplied with a DC high voltage from the outside to fix the substrate 134 with an electrostatic force. The substrate holder 132 may include a power electrode 135 receiving power from the RF power source. The electrode 136 of the electrostatic chuck may be disposed on the power electrode 135.

The substrate 134 may be a semiconductor substrate, a glass substrate, or a plastic substrate. The semiconductor substrate may be a silicon wafer of 300 mm.

The RF power source 146 may provide RF power to the power electrode 135. The RF power source 146 may be an RF power source of more than 13.56 MHz and less than 60 MHz. A frequency of the RF power source 146 may be 20 MHz to 60 MHz. The RF power source 146 may operate in pulse mode or continuous mode. Preferably, the RF power source 146 may operate in pulse mode. The RF power source 146 may supply RF power to the power electrode 135 through an impedance matching network 148.

The pulse control unit 149 may control the RF power source 146 and the DC pulse power source 142. Each of the DC pulse power source and the RF power source may operate in pulse mode.

The RF power of the RF power source 146 may generate capacitively-coupled plasma between the substrate 134 and the main baffle 160. A first plasma sheath a may be generated between the substrate and the plasma. A second plasma sheath b may be generated between the main baffle 160 and the plasma. The first plasma sheath a and the second plasma sheath b may be capacitors in a circuit. A first DC bias Va may be applied to the first plasma sheath a, and a second DC voltage Vb may be applied to the second plasma sheath b. An area in which the plasma and the substrate 134 are in contact with each other may be a first area Aa, and an area in which the plasma and the main baffle 160 are in contact with each other may be a second area Ab.

The energy of the ions incident on the substrate 134 may depend on the first DC bias Va. Accordingly, the second area Ab in which the main baffle 160 and the plasma are in contact with each other may be increased to increase the first DC bias Va. For example, the lower baffle 164 may have a second through-hole 164a, large enough for the plasma to permeate therethrough, to increase the second area Ab.

The DC pulse power source 142 may operate in pulse mode, and the RF power source 146 may operate in continuous (CW) mode.

According to a modified embodiment of the present disclosure, each of the DC pulse power source 142 and the RF power source 146 may operate in pulse mode. The RF power source 146 may include a first interval having first power and a second interval having second power lower than the first power. The DC pulse power source may be turned on within the second interval.

According to a modified embodiment of the present disclosure, the RF power may be turned off in a second on-time interval.

A capacitor 149 may be disposed between the DC pulse power source 142 and the substrate holder 132. The capacitor 149 may be a variable capacitor. The RF power source 146 may be connected to the substrate holder 132 through the capacitor 149.

An RF filter 144 may be disposed between the DC pulse power source 142 and the capacitor 149. The RF filter 144 may block a high-frequency signal of the RF power source 146. For example, the RF filter 144 may prevent the high-frequency signal of the RF power source 146 from being applied to a side of the DC pulse power source 142. Output terminals of the filter 144 and the impedance matching network 148 may be combined with each other and then connected to the capacitor 149.

Capacitance of the capacitor 149 may be smaller than parasitic capacitance Cp of a parasitic capacitor of the substrate holder 132. A frequency of the DC pulse power source 142 may be smaller than RC delay time that is a product of equivalent capacitance of the capacitance C of the capacitor 149 and the parasitic capacitance Cp of the parasitic capacitor of the substrate holder and the equivalent resistance R of the main plasma. The DC pulse power source 142 may be a bipolar spike pulse on a side of the main plasma. The capacitance of the capacitor 149 may be smaller than the capacitance of the parasitic capacitor of the substrate holder 132. Accordingly, the capacitor 149 may serve as an RC differentiator for the DC pulse power source 142. The frequency of the DC pulse power source 142 may be at the level of several hundred kHz. An on-duty ratio of the DC pulse power source 142 may be less than 0.5.

The positive spike pulse may reduce a difference in voltages between the main plasma and the substrate 134 to inject electrons into the substrate 134. The negative spike pulse may increase the difference in voltages between the main plasma and the substrate 134, so that ions may be incident on the substrate 134 with high energy. The positive spike pulse may supply electrons to a lower surface of a high aspect ratio etching pattern to neutralize cations. A width of the positive spike pulse may be less than 1 usec. Preferably, the width of the positive spike pulse may be less than 0.1 usec.

In a given DC pulse period, the width of the positive spike pulse may depend on the capacitance C of the capacitor 149. As the capacitance C of the capacitor increases from C′ to C″, the width of the positive spike pulse may increase. As the capacitance C of the capacitor increases from C″ to C′″, the width of the positive spike pulse may further increase.

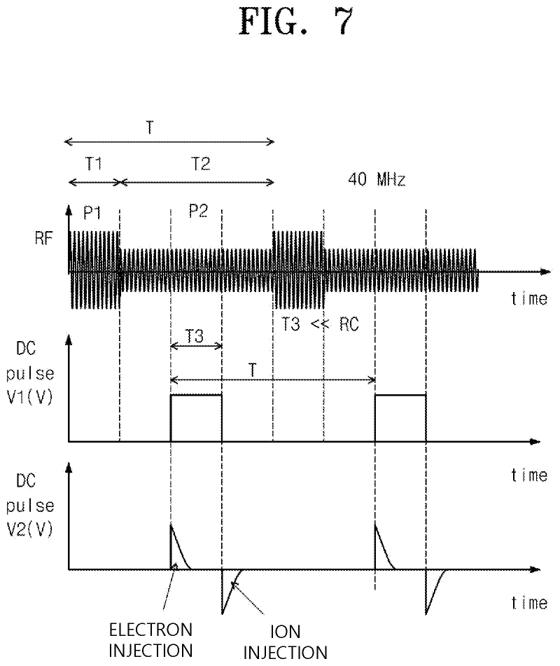

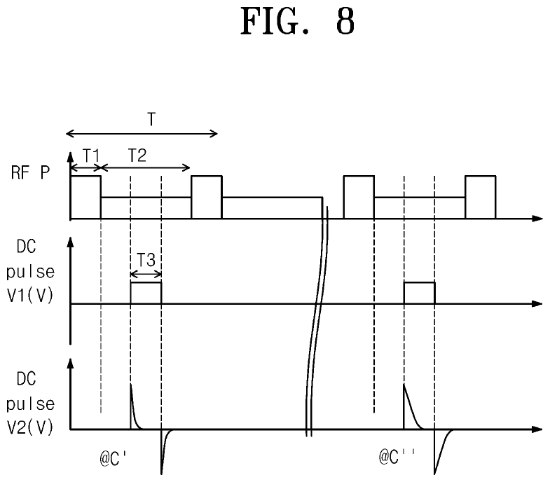

FIG. 7 is a diagram illustrating signals of the RF power and the DC pulse power of the plasma substrate treatment apparatus of FIG. 1.

Referring to FIG. 7, the pulse control unit 149 may control the RF power 146 and the DC pulse power 142. Each of the DC pulse power source 142 and the RF power source 146 may operate in pulse mode. The RF power may include a first interval T1 having first power P1 and a second interval T2 having second power P2 lower than the first power. The DC pulse power source 142 may be turned on within the second interval T2. The RF power may provide minimum power sufficient to maintain the plasma in the second interval T2. A turn-on interval T3 of the DC pulse power source 142 may be less than or equal to the second interval T2.

The positive spike pulse may reduce a difference in voltages between the plasma and the substrate to inject ions into the substrate. The negative spike pulse may increase the difference in voltages between the plasma and the substrate, so that ions may be incident on the substrate with high energy. The positive spiking pulse may supply electrons to a lower surface of the high aspect ratio etching pattern to neutralize cations. A width of the positive spike pulse may be less than 1 usec. Preferably, the width of the positive spike pulse may be less than 0.1 usec.

According to a modified embodiment of the present disclosure, the RF power may include a first interval having first power and a second interval having second power lower than the first power. In the second interval, the RF power may be turned off.

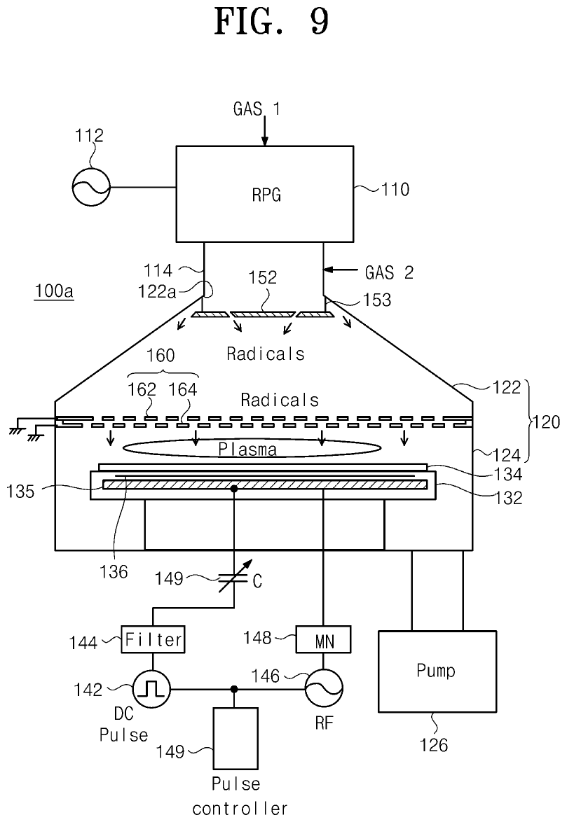

FIG. 8 is a diagram illustrating signals of the RF power and the DC pulse power of the plasma substrate treatment apparatus of FIG. 1.

Referring to FIG. 8, as the substrate processing apparatus 100 performs a process, the capacitance C of the capacitor 149 may be changed. Accordingly, the width of the positive spike pulse may vary depending on the capacitance of the capacitor. For example, in high-aspect-ratio etching, an etching depth may increase as the etching is performed. Accordingly, the width of the positive spike pulse may be increased to supply cations and electrons to a deeper hole or trench.

FIG. 9 is a conceptual diagram illustrating a plasma substrate treatment apparatus according to an embodiment of the present disclosure.

Referring to FIG. 9, the plasma substrate processing apparatus 100a may include: a remote plasma generator 110 generating remote plasma and active species; an upper chamber 122 having an opening 122a connected to an output port 114 of the remote plasma generator 110 and diffusing the active species provided by the remote plasma generator; a lower chamber 124 receiving the diffused active species from the upper chamber 122; a main baffle 160 partitioning the upper chamber and the lower chamber and allowing the active species to permeate therethrough; a substrate holder 132 supporting a substrate disposed within the lower chamber; an RF power 146 applying RF power to the substrate holder 132 to generate main plasma; and a DC pulse power source 142 applying a DC pulse to the substrate holder 132.

The RF power 146 may be connected to the substrate holder 132 through an impedance matching network 148. The DC pulse power 142 may be connected to a capacitor 149 through a filter 142, and the capacitor 149 may be connected to the substrate holder 132.

FIG. 10 is a perspective view illustrating a main baffle according to an embodiment of the present disclosure.

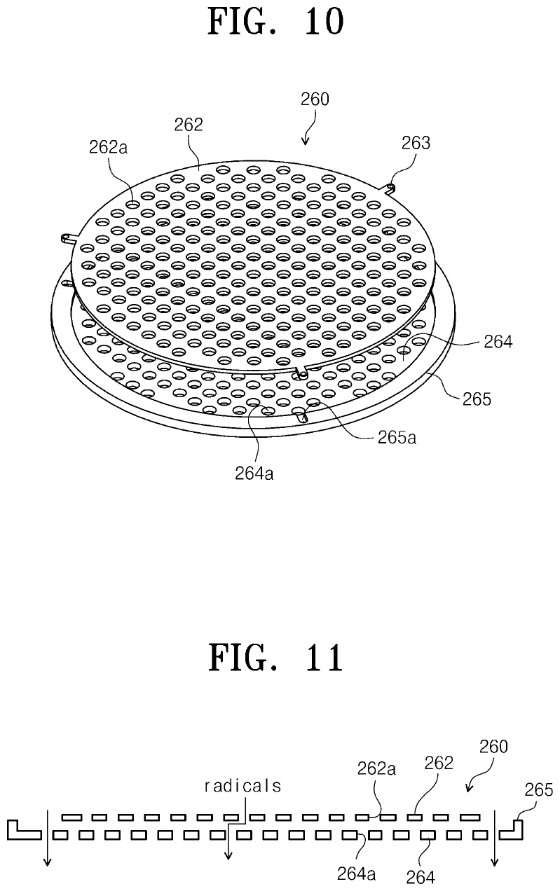

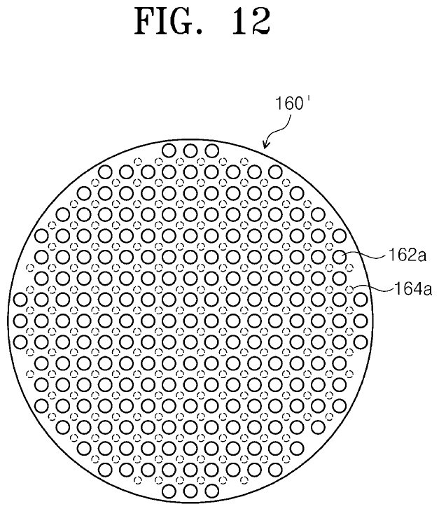

FIG. 11 is a cross-sectional view illustrating a substrate holder and a main baffle of a plasma substrate treatment apparatus of FIG. 10.

Referring to FIGS. 10 and 11, a main baffle 260 may include: an upper baffle 262 electrically grounded, opposing an upper chamber, and including a plurality of first through-holes 262a; and a lower baffle 264 electrically grounded, spaced apart from the upper baffle, and including a plurality of second through-holes 264a. The second through-holes 264a may be disposed to avoid overlapping the first through-holes 262a.

A diameter of the upper baffle 262 may be smaller than a diameter of the lower baffle 264. The diameter of the first baffle 152 is about 100 to 150 mm, and the diameter of the main baffle 260 is about 400 mm. The main baffle 260 may have a structure allowing active species to uniformly diffuse at a minimum distance from the substrate. Due to a difference in diameter between the first baffle 152 and the main baffle 260, the density of active species in a center portion of the main baffle 260 may be higher than at an edge thereof. The diameter of the upper baffle 262 may be larger than the diameter of the lower baffle 264 to prevent a non-uniform spatial distribution of active species density in the upper chamber 122 from being transferred to the lower chamber 124. Accordingly, a larger number of active species may flow to an outer portion of the main baffle 260. As a result, a uniform spatial distribution of active species density may be obtained in the lower chamber.

The lower baffle 264 has a ring-shaped projection 265 protruding at an outermost portion, and the ring-shaped projection 265 may include a protrusion 265a protruding for alignment with the upper baffle 262. The upper baffle 262 may have a smaller diameter than the lower baffle 264, but may include a plurality of bridges 263 extending in a radial direction. The bridges 263 may be coupled and fixed to the projection 265a.

FIG. 12 is a plan view illustrating a main baffle according to another embodiment of the present disclosure.

Referring to FIG. 12, a main baffle 160′ may include: an upper baffle 162 electrically grounded, opposing an upper chamber, and including a plurality of first through-holes 162a; and a lower baffle 164 electrically grounded, spaced apart from the upper baffle, and including a plurality of second through-holes 164a. A diameter of the first through-holes 162a of the upper baffle may be smaller than a diameter of the second through-holes 164a of the lower baffle. The second through-holes 164a may be disposed to avoid overlapping the first through-holes 162a. A diameter of the first through-hole 162a may be smaller than a thickness of a plasma sheath in the main baffle. Accordingly, plasma may not permeate from a lower portion to an upper portion through the first through-hole 162a. However, active species may freely permeate through the first through-hole 162a from an upper portion to a lower portion.

However, when the diameter of the first through-holes 162a is smaller than the thickness of the plasma sheath, the second through-hole 164a may be disposed to overlap the first through-hole 162a. In addition, the number of first through-holes 162a may be sufficiently larger than the number of second through-holes 164a. Accordingly, each of the upper and lower baffles may provide a similar open area ratio (open area/total area) to provide similar conductance.

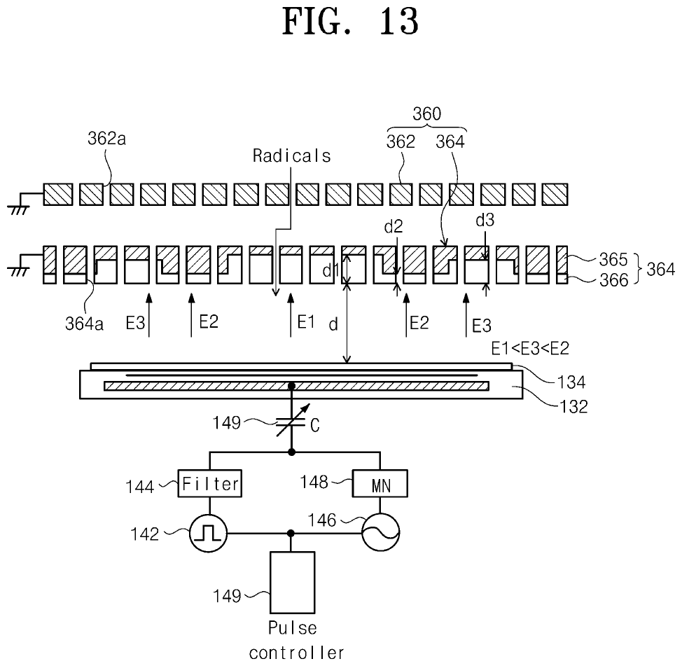

FIG. 13 is a conceptual diagram illustrating a main baffle according to another embodiment of the present disclosure.

FIG. 14 is a cut-away perspective view illustrating a lower baffle of the main baffle of FIG. 13.

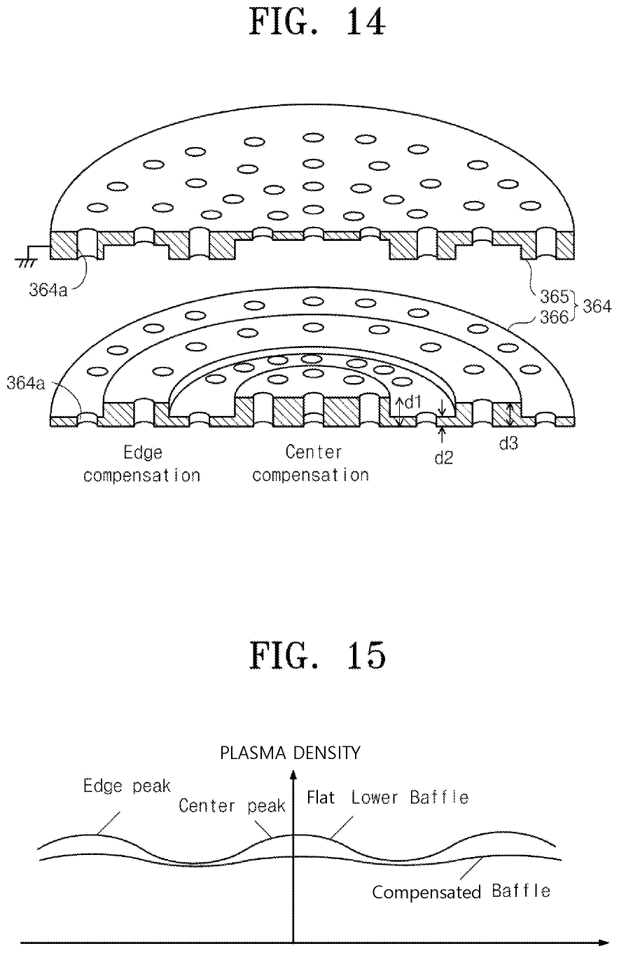

FIG. 15 is a diagram illustrating a change in plasma density by the main baffle of FIG. 13.

Referring to FIGS. 13 to 15, the main baffle 360 includes: an upper baffle 363 electrically grounded and including a plurality of first through-holes 362a opposing the upper chamber; and a lower baffle 364 electrically grounded and spaced apart from the upper baffle and including a plurality of second through-holes 364a.

The lower baffle 364 may include a perforated plate 365 formed of a conductor and a compensation plate 366 disposed below the perforated plate 365 and being an insulator having a dielectric constant or a semiconductor. The second through-holes 364a of the lower baffle 364 may be disposed to penetrate through the perforated plate 365 and the compensation plate 366. The lower baffle 364 may have a constant thickness, and a thickness of the perforated plate 365 may vary depending on a location. A thickness of the compensation plate 366 may vary depending on a location to maintain the thickness of the lower baffle 364 constant.

The compensation plate 366 may include at least one of silicon, silicon oxide, silicon nitride, or silicon oxynitride. The thickness of the compensation plate 366 may be greatest in at least one of a central region and/or an edge region. The central region may have a circular shape, and the edge region may be a ring shape.

As a frequency of the RF power source 146 increases, a standing wave effect or a harmonic effect may occur. The standing wave effect and the harmonic effect may increase as the frequency increases, and may form a center peak and/or an edge peak of plasma density.

As the frequency of the RF power source 146 increases, the plasma density may increase and electron temperature may decrease, so that various process environments may be established.

Conventionally, a surface step may be provided on a power electrode applied with RF power source to spatially adjust the magnitude of an electric field in capacitively-coupled plasma. However, the surface step of the power electrode may cause contaminants to be deposited to form particles. Even when the power source has a surface curvature, it may be difficult to manufacture such a curvature electrode and such a curvature electrode may interfere with a flow of the fluid to cause difficulty in providing a spatially uniform process.

According to an embodiment of the present disclosure, the perforated plate 365 of the lower baffle 364 acting as a grounded electrode may have a curvature or step on a lower surface thereof. The surface curvature or step of the perforated plate 365 may spatially adjust a gap d between the lower baffle 364 and the substrate holder 132 applied with the RF power source to adjust the magnitude of the electric field at each location.

The lower baffle 364 may have a second through-hole 364a. When a thickness of the lower baffle 364 varies depending on a location, conductance of the second through-hole 3 64a may vary. The lower baffle 364 may have a multilayer structure and may be planarized with a constant thickness to suppress an effect on a fluid flow in a discharge space while maintaining conductance of the second through-hole 364a constant.

Specifically, the lower baffle 364 may include a perforated plate 365, formed of a conductor, and a compensation plate 366 disposed below the perforated plate and being an insulator having a dielectric constant or a semiconductor. The compensation plate 366 may be an insulator having a dielectric constant or a semiconductor. The second through-hole 364a of the lower baffle may be disposed to penetrate through the perforated plate and the compensation plate. Accordingly, a lower surface of the lower baffle 364 may be the same plane.

In a discharge region, magnitudes of electric fields E1, E, and E3 may be determined by thicknesses d1, d2, d3 of the compensation layer 366, a dielectric constant of the compensation layer, and a height d of the discharge region. That is, as the dielectric constant of the compensation layer 366 decreases, the magnitude of the electric field E1 may be easily changed. Accordingly, a material of the compensation layer 366 may be silicon oxide, silicon nitride, silicon oxynitride, aluminum oxide, or silicon.

The thickness of the compensation layer 366 may be about ½ to 1/10 of the height d of the discharge region. For example, when the height d of the discharge region is 10 mm, the maximum thickness d1 of the compensation layer 366 may be 5 mm to 1 mm. The thicker the compensation layer 366, the lower the electric field strength in the corresponding discharge region. When d1>d3>d2, then E1<E3<E2. Accordingly, the thickness of the compensation layer 366 may be selected depending on a location to suppress the center peak and/or edge peak of the plasma density.

According to a modified embodiment, the thickness of the compensation layer 366 changes abruptly depending on a location, but may change gradually.

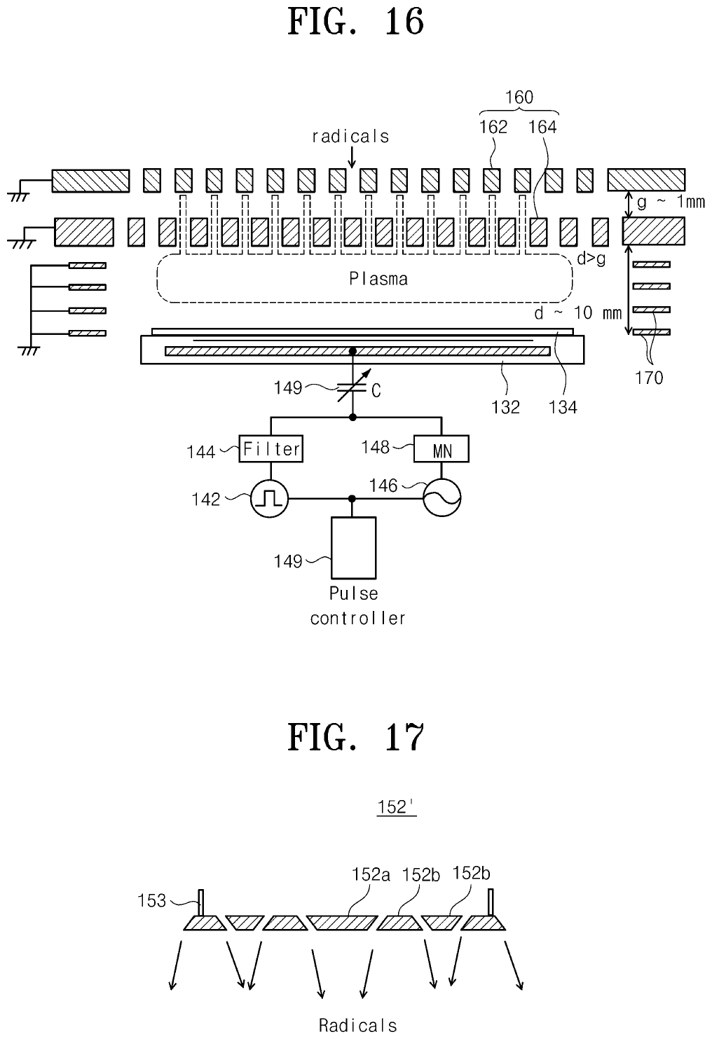

FIG. 16 is a conceptual diagram illustrating a substrate treatment apparatus according to another embodiment of the present disclosure.

Referring to FIG. 16, a plasma substrate processing apparatus 100 according to an embodiment of the present disclosure may include: a remote plasma generator 110 generating plasma and active species; an upper chamber 122 having an opening 120a connected to the output port 114 of the remote plasma generator 110 and receiving and diffusing the active species of the remote plasma generator 110; a plasma blocking baffle 152 disposed in the opening of the upper chamber 122; a lower chamber 124 receiving the active species diffused in the upper chamber 122; a main baffle 160 partitioning the upper chamber 122 and the lower chamber 124 and allowing the active species to permeate therethrough; a substrate holder 134 supporting a substrate 134 disposed in the lower chamber 160; and an RF power source 146 applying RF power to the substrate holder 134.

In a cylindrical cavity structure surrounding a parallel plate capacitor, a resonant frequency of standing wave may be inversely proportional to a radius of the lower chamber 124. Accordingly, as a diameter of the lower chamber 124 increases, the resonant frequency may decrease. For example, when the radius of the lower chamber is 0.3 m, the resonant frequency may be about 300 MHz. When the frequency of the RF power source 142 is 100 MHz, third harmonics may match the resonant frequency to significantly generate a standing wave effect. Accordingly, the radius of the lower chamber does not need to be reduced to increase the resonant frequency of the resonator by the lower chamber.

At least one ground ring 170 may be disposed to surround the discharge region to effectively reduce the radius of the lower chamber. Accordingly, the resonant frequency may increase, the standing wave effect may be reduced, and an area of the ground surface that is in contact with plasma may increase. The resonant frequency is achieved by the harmonics of the RF power source 142, so that when the frequency of the RF power source 142 is used below 60 MHz, the standing wave effect may be reduced.

The ground ring 170 may be disposed below the main baffle 160 to surround the plasma between the substrate holder 132 and the main baffle 160, and may have a washer shape. An inner diameter of the ground ring 170 may be larger than an outer diameter of the substrate holder 132. The ground ring 170 may limit a discharge space to limit a space in which the plasma diffuses. In addition, the ground ring 170 may be grounded to increase a ground area and increase a DC bias voltage applied to the substrate 134. The ground rings 170 may be disposed to vertically stacked and to be spaced apart from each other, so that neutral gas may be exhausted to a space between the ground rings 170. A material of the ground ring 170 may be a conductive material, and may be metal or a metal-alloy.

FIG. 17 is a cross-sectional view illustrating a plasma blocking baffle according to another embodiment of the present disclosure.

Referring to FIG. 17, the first baffle 152′ may include: a disk 152a having an inclined outer surface; and a plurality of ring plates 152b having an inclined inner surface and an inclined outer surface and disposed to surround the disk 152a at a predetermined gap from the disk 152a.

A space between the disk 152a and the ring plate 152b and a space between the ring plates 152b may form a concentric slit. Active species, passing through the concentric slit between the disk 152a and the ring plate 152b, may diffuse toward a center of the upper chamber.

Active species, passing through the concentric slit between the ring plates 152b, may diffuse toward a wall of the upper chamber. The first baffle 152′ may spatially distribute the active species to achieve rapid diffusion. Accordingly, a height of the upper chamber 122 may decrease.

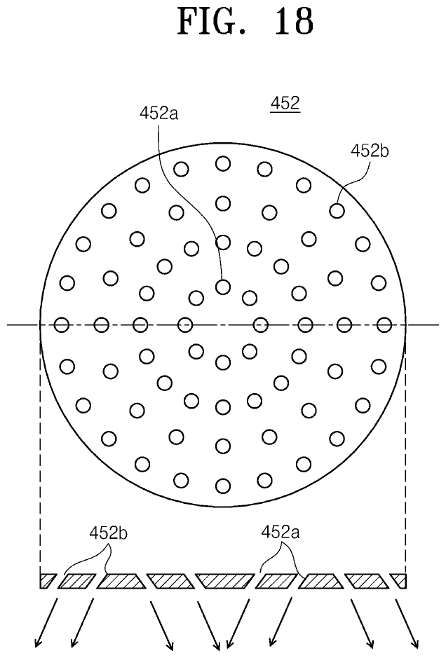

FIG. 18 is a cross-sectional view showing the plasma blocking baffle according to another embodiment of the present disclosure.

Referring to FIG. 18, the plasma blocking baffle 452 may include a plurality of through-holes 452a and 452b in an oblique direction. The through-holes 452a in a central region may be inclined to inject active species in a direction of a central axis. The through-holes 452b in an edge region may be inclined to inject active species toward a wall of an upper chamber. The plasma blocking baffle 452 may spatially distribute the active species to achieve rapid diffusion. Accordingly, a height of the upper chamber may be reduced.

Although the present disclosure and its advantages have been described in detail, it should be understood that various changes, substitutions and alterations can be made herein without departing from the spirit and scope of the disclosure as defined by the following claims.

1. A plasma substrate treatment apparatus comprising:
a remote plasma generator generating remote plasma and active species;
an upper chamber having an opening connected to an output port of the remote plasma generator and receiving and diffusing the active species from the remote plasma generator;
a lower chamber receiving the diffused active species from the upper chamber;
a main baffle partitioning the upper chamber and the lower chamber and allowing the active species to permeate therethrough;
a substrate holder supporting a substrate disposed within the lower chamber;
an RF power source applying RF power to the substrate holder to generate main plasma; and
a DC pulse power source applying a DC pulse to the substrate holder.

2. The plasma substrate treatment apparatus as set forth in claim 1, wherein the RF power source is an RF power source of more than 13.56 MHz and less than 60 MHz.

3. The plasma substrate treatment apparatus as set forth in claim 1, further comprising:
a pulse control unit controlling the DC pulse power source and the RF power source,
wherein
each of the DC pulse power source and the RF power source operates in pulse mode,
the RF power source comprises a first interval having first power and a second interval having second power lower than the first power, and
the DC pulse power source is turned on within the second interval.

4. The plasma substrate treatment apparatus as set forth in claim 1, further comprising:
a capacitor disposed between the DC pulse power and the substrate holder,
wherein
the RF power source is connected to the substrate holder through the capacitor.

5. The plasma substrate treatment apparatus as set forth in claim 4, further comprising:
an RF filter disposed between the DC pulse power source and the capacitor,
wherein
the RF filter blocks an RF signal of the RF power source.

6. The plasma substrate treatment apparatus as set forth in claim 4, wherein
capacitance of the capacitor is smaller than parasitic capacitance of a parasitic capacitor of the substrate holder,
a frequency of the DC pulse power source is smaller than RC delay time that is a product of equivalent capacitance of the capacitance of the capacitor and the parasitic capacitance of the parasitic capacitor of the substrate holder and equivalent resistance of the main plasma, and
the DC pulse power source is a bipolar spike pulse on a side of the main plasma.

7. The plasma substrate treatment apparatus as set forth in claim 2, wherein
capacitance of the capacitor is smaller than capacitance of a parasitic capacitor of the substrate holder, and
the capacitor acts as an RC differentiator for the DC pulse power source.

8. The plasma substrate treatment apparatus as set forth in claim 1, further comprising:
a plasma blocking baffle disposed in the opening of the upper chamber.

9. The plasma substrate treatment apparatus as set forth in claim 1, wherein
the main baffle comprises:
an upper baffle electrically grounded and opposing the upper chamber and comprising a plurality of first through-holes; and
a lower baffle electrically grounded and spaced apart from the upper baffle and comprising a plurality of second through-holes.

10. The plasma substrate treatment apparatus as set forth in claim 8, wherein
the second through-hole is disposed to avoid overlapping the first through-hole.

11. The plasma substrate treatment apparatus as set forth in claim 9, wherein
a diameter of the second through-holes is more than twice a thickness of the plasma sheath between the lower baffle and plasma, and
the plasma permeates into the second through-hole.

12. The plasma substrate treatment apparatus as set forth in claim 9, wherein
a gap between the upper baffle and the lower baffle is less than or equal to several millimeters, and
a gap between the substrate holder and a lower surface of the upper baffle is larger than the gap between the upper baffle and the lower baffle.

13. The plasma substrate treatment apparatus as set forth in claim 9, wherein
a diameter of the first through-hole of the upper baffle is smaller than a diameter of the second through-hole of the lower baffle.

14. The plasma substrate treatment apparatus as set forth in claim 13, wherein
the second through-hole is disposed to avoid overlapping the first through-hole.

15. The plasma substrate treatment apparatus as set forth in claim 9, wherein
a diameter of the upper baffle is smaller than a diameter of the lower baffle.

16. The plasma substrate treatment apparatus as set forth in claim 8, wherein
the plasma blocking baffle comprises:
a disk having an inclined outer surface; and
a ring plate having an inclined inner surface and an inclined outer surface and disposed to surround the disk at a predetermined distance from the disk,
the outer surface of the disk has an outer diameter increasing with height, and
the inner surface of the ring plate has an inner diameter increasing with height.

17. The plasma substrate treatment apparatus as set forth in claim 16, wherein
the disk and the ring plate are fixed by a plurality of bridges, and
the ring plate is fixed to the upper chamber by a plurality of columns.

18. The plasma substrate treatment apparatus as set forth in claim 8, wherein
the plasma blocking baffle comprises a plurality of through-holes,
through-holes disposed in a central portion of the plasma blocking baffle are holes inclined to be directed toward a central axis, and
the through-holes disposed in an edge of the plasma blocking baffle are holes inclined to be directed toward the outside.

19. The plasma substrate treatment apparatus as set forth in claim 1, further comprising:
at least one ground ring,
wherein
the ground ring is disposed below the main baffle to surround plasma between the substrate holder and the main baffle and has a ring shape, and
an inner diameter of the ground ring is larger than an outer diameter of the substrate holder.

20. The plasma substrate treatment apparatus as set forth in claim 1, wherein
the main baffle comprises:
an upper baffle electrically grounded, opposing the upper chamber, and comprising a plurality of first through-holes; and
a lower baffle electrically grounded, spaced apart from the upper baffle, and comprising a plurality of second through-holes,
the lower baffle comprises:
a perforated plate formed of a conductor; and
a compensation plate that is an insulator or a semiconductor having a dielectric constant, and disposed below the perforated plate, and
the second through-hole of the lower baffle is disposed to penetrate through the perforated plate and the compensation plate.

21. The plasma substrate treatment apparatus as set forth in claim 20, wherein
the lower baffle has a constant thickness,
a thickness of the perforated plate varies depending on a location, and
a thickness of the compensation plate varies depending on a location to maintain a thickness of the lower baffle constant.

22. The plasma substrate treatment apparatus as set forth in claim 20, wherein
the compensation plate comprises at least one of silicon, silicon oxide, silicon nitride, or silicon oxynitride.

23. The plasma substrate treatment apparatus as set forth in claim 21, wherein
a thickness of the compensation plate is largest in at least one of a central region and an edge region,
the central region has a circular shape, and
the edge region has a ring shape.

24. The plasma substrate treatment apparatus as set forth in claim 1, wherein
the remote plasma generator is an inductively-coupled plasma source comprising an induction coil wound around a dielectric cylinder.

25. The plasma substrate treatment apparatus as set forth in claim 1, wherein
the output port of the remote plasma generator has a diameter ranging from 50 millimeters to 150 millimeters,
the upper chamber has a truncated cone shape, and
the opening of the upper chamber is disposed in a truncated portion.
